(19) United States
(12) Patent Application Publication
(10) Pub. No.: US 2006/0030101 A1
(43) Pub. Date: Feb. 9, 2006

(54) Semiconductor device and method for fabricating the same

(76) Inventor: Eun Jong Shin, Mapo-gu (KR)

Correspondence Address: MCKENNA LONG & ALDRIDGE LLP, 1900 K STREET, NW, WASHINGTON, DC, 20006, US

(21) Appl. No.: 11/197,331

(22) Filed: Aug. 5, 2005

(30) Foreign Application Priority Data
Aug. 6, 2004 (KR) 2004-0061998

(51) Int. Cl. H01L 21/8242

(52) U.S. Cl. 438/253; 438/239; 257/306

(57) ABSTRACT

A method for fabricating a MIM capacitor with fewer process steps and decreased production cost. The method includes forming a via and a capacitor opening by selectively etching an insulating interlayer, wherein the via exposes the lower metal line and the capacitor opening is wider than the via, forming a first metal layer on the insulating interlayer at a thickness suitable for completely filling the inside of the via, burying the capacitor opening by forming a dielectric layer on the first metal layer inside the capacitor opening, and simultaneously forming an upper metal line and a second metal layer on the via and the dielectric layer by forming and patterning a metal layer.

### CROSS-REFERENCE TO RELATED APPLICATIONS

This application claims the benefit of Korean Application No. P2004-61998 filed on Aug. 6, 2004, which is hereby incorporated by reference as if fully set forth herein.

### BACKGROUND OF THE INVENTION

1. Field of the Invention

The present invention relates to a method for fabricating a semiconductor device, and more particularly, to a semiconductor device including a metal-insulator-metal (MIM) structure and a method for fabricating the semiconductor device.

2. Discussion of the Related Art

Currently, semiconductor devices having high-capacitance capacitors are being researched for application in analog circuits requiring high operation speed. Generally, capacitors have a polysilicon-insulator-polysilicon structure, wherein the lower and upper electrodes are formed of polysilicon. However, in these structures, an oxidation reaction is generated at the interface between the lower and upper electrodes and the dielectric thin film. This results in the formation of an oxide layer that causes the entire capacitance of the device to decrease.

In order to overcome this problem, the capacitor structure is changed to metal-insulator-silicon (MIS) or metal-insulator-metal (MIM). A MIM capacitor structure is usually used for a semiconductor device of high capacitance because it provides low resistivity with no parasitic capacitance generated by depletion.

FIGS. 1A to 1B illustrate a method for fabricating a MIM capacitor according to the related art. As shown in FIG. 1A, an insulating interlayer 3 is formed on an upper structure 2 of a semiconductor substrate 1. A first metal layer 4, a dielectric layer 5 and a second metal layer 6 are then sequentially formed on the insulating interlayer 3. After that, a photoresist pattern 10 (not shown) is formed on the second metal layer 6, wherein the photoresist pattern 10 is formed as a mask pattern for the formation of a capacitor top metal (CTM) in the MIM capacitor.

As shown in FIG. 1A, when etching the second metal layer 6, a metallic polymer 20 is generated as by-products. When the metallic polymer 20 deposits on the sidewalls of the dielectric layer 5 it deteriorates the characteristics of MIM capacitor.

Referring to FIG. 1B, another insulating interlayer 7 is formed over the first and second metal layers. Insulating interlayer 7 is formed and then selectively etched using a photoresist pattern (not shown) as a mask, thereby forming vias 8 for exposing the first metal layer 4 and the second metal layer 6. The vias 8 are then filled with a conductive material 9.

The method for fabricating the capacitor of MIM structure according to the related art has a number of disadvantages.

The method for fabricating the MIM capacitor structure according to the related art, uses two separate photolithography steps for patterning the CTM layer and the vias. As a result, the process for fabricating the MIM capacitor is more complicated and more expensive. Additionally, the characteristics of the MIM capacitor are deteriorated due to the metallic polymer generated during the etching of the second metal layer.

### SUMMARY OF THE INVENTION

Accordingly, the present invention is directed to a method for fabricating a MIM capacitor that substantially obviates one or more problems due to limitations and disadvantages of the related art.

An advantage of the present invention is to provide a simpler method for fabricating a MIM capacitor with decreased production costs.

Another advantage of the present invention is to provide a method for fabricating a MIM capacitor that removes foreign materials from sidewalls of the capacitor.

Additional advantages, and features of the present invention will be set forth in the description which follows, and in part will be apparent from the description, or may be learned by practice of the invention. The objectives and other advantages of the invention may be realized and attained by the structure particularly pointed out in the written description and claims hereof as well as the appended drawings.

To achieve these and other advantages and in accordance with the purpose of the present invention, as embodied and broadly described herein, a semiconductor device having a first metal layer, a second metal layer over the first metal layer, and a dielectric layer between the first and second metal layers, wherein the dielectric layer has an upper surface that is co-planar with at least a portion of an upper surface of the first metal layer.

In one embodiment of the present invention, the semiconductor device includes a lower metal line over a semiconductor substrate, an insulating interlayer including a via and a capacitor opening over the lower metal line and semiconductor substrate, wherein the via exposes the lower metal line and wherein the via and the capacitor opening have the same depth. A first metal layer if formed on the inner sidewalls and bottom of the capacitor opening, and inside the via. A dielectric layer is formed on the first metal layer inside the capacitor opening, wherein the dielectric layer buries the capacitor opening. An upper metal line is formed on the via and a second metal layer is formed on the dielectric layer, wherein the second metal layer and the upper metal line are formed at the same thickness and formed of the same material.

The capacitor opening and the via may be formed to have sloped sidewalls. Additionally, the capacitor opening is formed to be wider than the via. The first metal layer may be formed of tungsten. The dielectric layer may include an oxide-nitride-oxide layer. The upper metal line and the second metal layer may be formed of any one of Al, Al alloy and Cu.

The upper surface of the insulating interlayer, the first metal layer and the dielectric layer may be planarized by CMP.

In another aspect of the present invention, a method for fabricating a semiconductor device may include forming a lower metal line over a semiconductor substrate, forming an insulating interlayer on the lower metal line and over the semiconductor substrate, and forming a via and a capacitor opening by selectively etching the insulating interlayer, wherein the via exposes the lower metal line and the capacitor opening is wider than the via. The method may further include forming a first metal layer on the insulating interlayer at a thickness suitable for completely filling the via. Burying the capacitor opening by forming a dielectric layer on the first metal layer inside the capacitor opening, and simultaneously forming an upper metal line over the via and a second metal layer over the dielectric layer by forming and patterning a third metal layer.

The process of forming the via and the capacitor opening may include the steps of forming a photoresist pattern on the insulating interlayer, wherein the photoresist pattern exposes predetermined portions for the via and the capacitor opening, and forming the via and the capacitor opening to have the same depth by etching the exposed insulating interlayer in state of using the photoresist pattern as a mask.

The process for forming the dielectric layer may include the steps of forming the dielectric layer on the insulating interlayer at a thickness suitable for completely burying the capacitor opening, and planarizing the dielectric layer by CMP until the insulating interlayer is exposed.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principle of the invention.

In the drawings:

FIGS. 1A to 1B are cross sectional views of the process for fabricating a MIM capacitor according to the related art; and

FIGS. 2A to 2D are cross sectional views of the process for fabricating a semiconductor device according to one embodiment of the present invention.

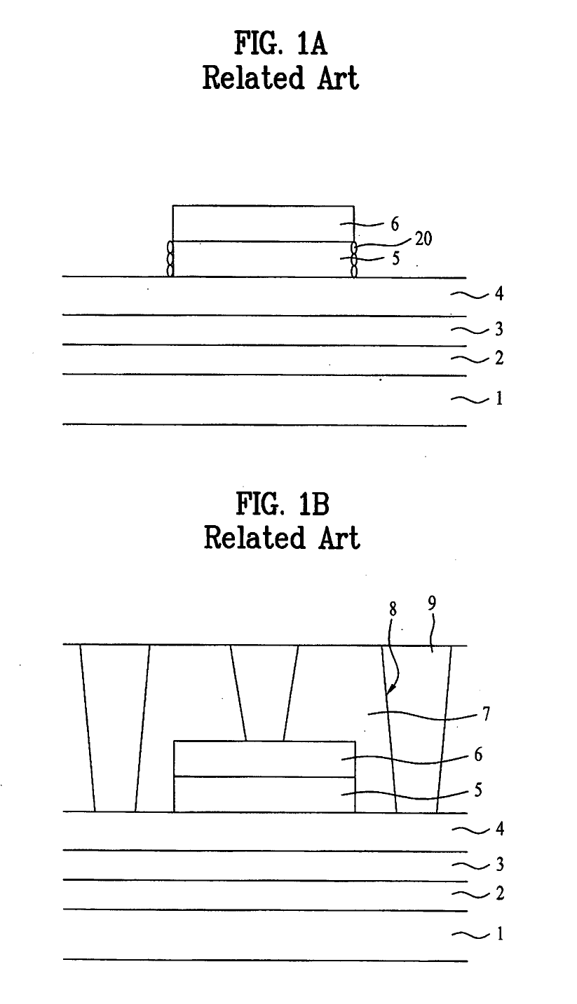

### DETAILED DESCRIPTION OF THE INVENTION

Reference will now be made in detail to an embodiment of the present invention, examples of which are illustrated in the accompanying drawings. Wherever possible, the same reference numbers will be used throughout the drawings to refer to the same or like parts.

A method for fabricating a semiconductor device according to the present invention will be described with reference to the accompanying drawings.

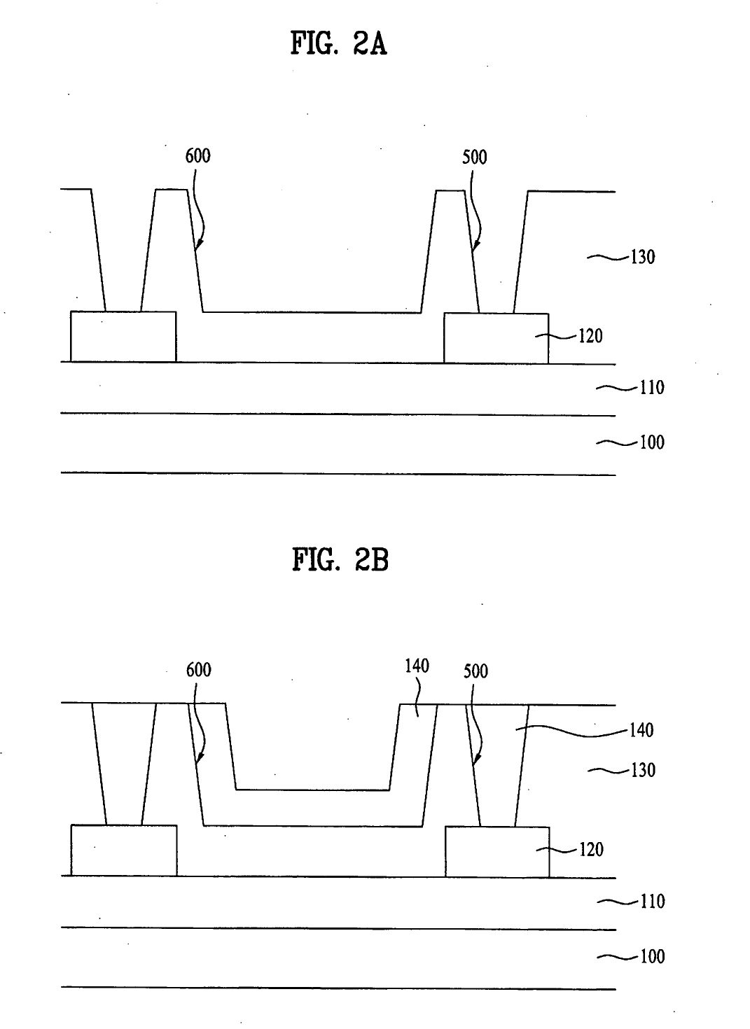

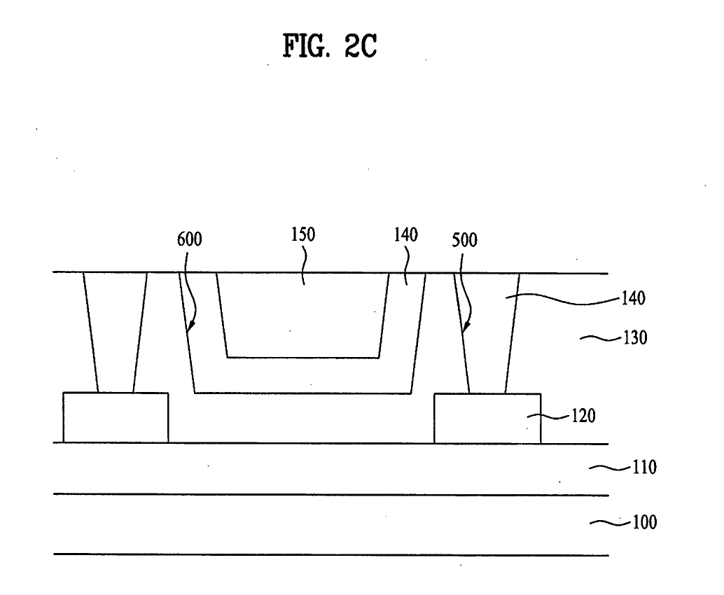

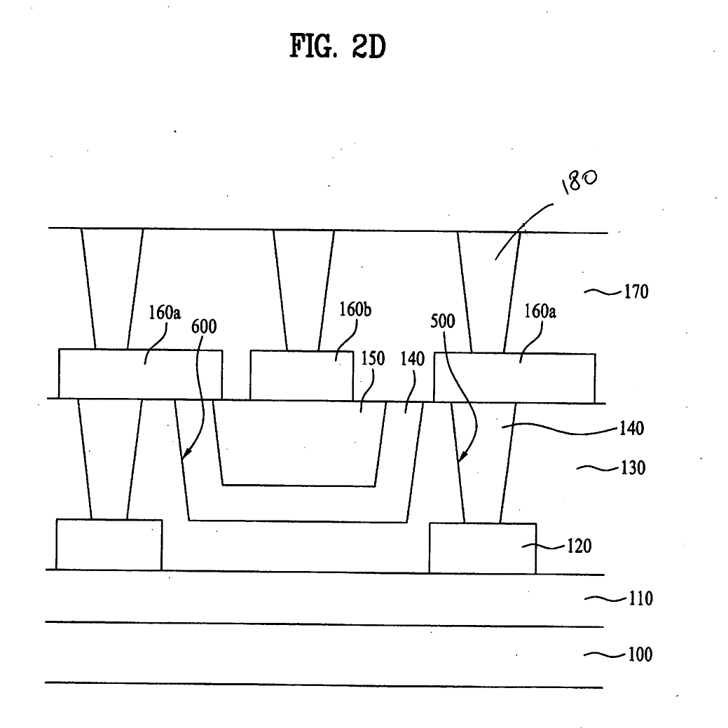

FIGS. 2A to 2D are cross sectional views of the process for fabricating a semiconductor device according to an embodiment of the present invention.

As shown in FIG. 2A, a structure 110 is formed on a semiconductor substrate 100, and a lower metal line 120 is formed on the structure 110. An insulating interlayer 130 is then formed on the lower metal line 120 and the structure 110.

The insulating interlayer 130 may be formed of USG(Undoped Silica Glass)-TEOS(Tetra Ethyl Ortho Silicate), or may be formed of FSG(Fluorine-doped Silica Glass)-SiH4.

The insulating interlayer 130 is then patterned to form via 500 and capacitor opening 600. The insulating interlayer 130 may be etched by a dry-etching process using Cl₂ gas. The via 500 and the capacitor opening 600 are formed at the same time in one photolithography step using one photoresist mask. Via 500 is formed so that it exposes a predetermined portion of the lower metal line 120. Additionally, via 500 and the capacitor opening 600 are formed to have the same depth, however, capacitor opening 600 is formed wider than via 500.

To improve conformity when depositing a layer on the inner sidewalls of the capacitor opening 600, the via 500 and the capacitor opening 600 may be formed to have sloped inner sidewalls.

Referring to FIG. 2B, a first metal layer 140, such as tungsten, is then deposited over insulating interlayer 130. Metal layer 140 is formed along the inner sidewalls of the capacitor openings 600 and inside the via 500. It is important to note that this first metal layer does not fill the capacitor opening and instead it is formed to have a constant thickness along the inner sidewalls and bottom of the capacitor opening 600. On the other hand, because via 500 is narrower than capacitor opening 600, the inside of via 500 is completely filled by the first metal layer 140.

To completely fill via 500, the first metal layer 140 is formed of a predetermined thickness so that the width of via 500 is smaller than and twice the thickness of the metal layer 140. For example, if via 500 has a width of 5000 Å to 7000 Å then the tungsten layer 140 may be deposited to have a thickness of 2500 Å to 3500 Å. After deposition, the first metal layer 140 may be planarized by a CMP (Chemical Mechanical Polishing) process until the insulating interlayer 130 is exposed. As a result, the upper surface of the insulating interlayer 130 is also planarized.

As shown in FIG. 2C, a dielectric layer 150 is then formed on the first metal layer 140 inside the capacitor opening 600 thereby burring capacitor opening 600. Dielectric layer 150 serves as the capacitor dielectric. Dielectric layer 150 may include any suitable material. For example, layer 150 may be an oxide-nitride-oxide (ONO) layer. The ONO layer may be formed by depositing a USG layer of a thickness of 1000 Å by HDP (High Density Plasma), followed by a SiN layer approximately 1000 Å to 1500 Å thick deposited by PECVD, and then a TEOS layer approximately 1000 Å thick deposited by PECVD.

After deposition, dielectric layer 150 is etched back by a CMP process until the insulating interlayer 130 is again exposed. Thus, the upper surface of the insulating interlayer 130, the first metal layer 140 and the dielectric layer 150 become planar.

Next, as shown in FIG. 2D, an upper metal line 160a is formed on via 500 and first metal layer 140, and a second metal layer 160b is formed on dielectric layer 150. The upper metal line 160a and the second metal layer 160b are made of the same material and have substantially the same thickness of approximately 3000Å to 4000Å. Suitable materials that may be used for upper metal line 160a and second metal layer 160b include Al, Al alloy, and Cu. Upper metal line 160a and second metal layer 160b are both patterned simultaneously in a single photolithography step using one photoresist mask To achieve the desired structure, the mask pattern used in this photolithography step includes a pattern for forming a capacitor top metal as a second metal layer of the MIM capacitor, and the pattern for forming the upper metal line 160a.

Barrier layers (not shown) may also be formed on the lower and upper surfaces of each of the upper metal line 160a and the second metal layer 160b. Each barrier layer may be composed of Ti and TiN. The lower barrier layers, for example, may be formed to have a Ti layer approximately 110 Å thick, and a TiN layer approximately 220 Å thick. The upper barrier layers, may, for example, be formed to have a Ti layer approximately 50 Å thick, and a TiN layer approximately 500 Å thick. For the barrier layers the Ti and TiN layers may be layered in any order.

Thereafter, the MIM capacitor is completed by first depositing insulating interlayer 170 over the upper metal line 160a, the second metal layer 160b and the insulating interlayer 130, and then etching insulating layer 170 to form upper vias 180.

As mentioned above, the semiconductor device and the method for fabricating the semiconductor device according to the present invention has the following advantages. According to the present invention the CBM and the via are form simultaneously. Additionally, the CTM and the upper metal line are also both formed in one step. This results in a more simplified process that is less expensive.

The present invention also avoids the problem of having the byproducts, generated when etching the CTM, deposit on the sidewalls of the dielectric layer. Accordingly, it is possible to stably operate the MIM capacitor, and to improve the reliability of device.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A semiconductor device comprising:
a first metal layer;
a second metal layer over the first metal layer; and
a dielectric layer between said first and second metal layers, wherein the dielectric layer has an upper surface that is co-planar with at least a portion of an upper surface of the first metal layer.

2. The semiconductor of claim 1, further comprising a via exposing a first metal line.

3. The semiconductor of claim 2, further comprising an upper metal line over the via.

4. The semiconductor of claim 1, wherein the first metal layer comprises tungsten and the second metal layer comprises any one of Al, Al alloy, and Cu.

5. The semiconductor of claim 1, wherein the dielectric layer comprises an oxide-nitride-oxide layer.

6. A semiconductor device comprising:
a lower metal line over a semiconductor substrate;
an insulating interlayer on the lower metal line and the semiconductor substrate;
the insulating interlayer comprising a via and a capacitor opening, wherein the via exposes the lower metal line and wherein the via and the capacitor opening have the same depth;
a first metal layer on the inner sidewalls and bottom of the capacitor opening, and inside the via;
a dielectric layer on the first metal layer and inside the capacitor opening, wherein the dielectric layer buries the capacitor opening;
an upper metal line over the via; and
a second metal layer over the dielectric layer, wherein the second metal layer and the upper metal line have substantially the same thickness and are formed of the same material.

7. The semiconductor device of claim 6, wherein the capacitor opening is wider than the via.

8. The semiconductor device of claim 6, wherein the first metal layer is formed of tungsten.

9. The semiconductor device of claim 6, wherein the dielectric layer comprises an oxide-nitride-oxide layer.

10. The semiconductor device of claim 6, wherein the upper metal line and the second metal layer are formed of any one of Al, Al alloy and Cu.

11. The semiconductor device of claim 6, wherein the upper surface of the insulating interlayer, the first metal layer and the dielectric layer are planar.

12. The semiconductor device of claim 6, wherein the via and the capacitor opening have sloped sidewalls.

13. A method for fabricating a semiconductor device comprising:
forming a lower metal line over a semiconductor substrate;
forming an insulating interlayer on the lower metal line and over the semiconductor substrate;
forming a via and a capacitor opening by selectively etching the insulating interlayer, wherein the via exposes the lower metal line and the capacitor opening is wider than the via;
forming a first metal layer over the insulating interlayer at a thickness suitable for completely filling the via;
burying the capacitor opening by forming a dielectric layer on the first metal layer inside the capacitor opening; and
simultaneously forming an upper metal line over the via and a second metal layer over the dielectric layer by forming and patterning a third metal layer.

14. The method of claim 13, wherein the dielectric layer comprises an oxide-nitride-oxide layer.

15. The method of claim 13, wherein the process of forming the via and the capacitor opening includes the steps of:
forming a photoresist pattern on the insulating interlayer, wherein the photoresist pattern exposes predetermined portions for the via and the capacitor opening; and
forming the via and the capacitor opening to have the same depth by etching the exposed insulating interlayer using the photoresist pattern as a mask.

16. The method of claim 13, wherein the first metal layer comprises tungsten.

17. The method of claim 13, wherein the process for forming the dielectric layer includes the steps of:
forming the dielectric layer on the insulating interlayer at a thickness sufficient for completely burying the capacitor opening; and
planarizing the dielectric layer by CMP until the insulating interlayer is exposed.

18. The method of claim 17, wherein the dielectric layer comprises an oxide-nitride-oxide layer.

19. The method of claim 13, wherein the metal layer comprises any one of Al, Al alloy and Cu.

20. The method of claim 13, further comprising forming the via and the capacitor opening to have sloped sidewalls.
